(19) United States
(12) Patent Application Publication
(10) Pub. No.: US 2025/0293725 A1
(43) Pub. Date: Sep. 18, 2025

(54) POWER PROCESSING CIRCUITS

(71) Applicant: ETRA SEMICONDUCTOR (SUZHOU) CO., LTD., Suzhou (CN)

(72) Inventors: Xinyu LIU, Suzhou (CN); Xiaowei ZHU, Suzhou (CN); Jun CHEN, Suzhou (CN)

(73) Assignee: ETRA SEMICONDUCTOR (SUZHOU) CO., LTD., Suzhou (CN)

(21) Appl. No.: 19/023,225

(22) Filed: Jan. 15, 2025

Related U.S. Application Data
(63) Continuation of application No. PCT/CN2024/128327, filed on Oct. 30, 2024.

(30) Foreign Application Priority Data
Mar. 12, 2024 (CN) 202410280779.0

(51) Int. Cl. H04B 1/40; H03H 7/42; H04L 25/02

(52) U.S. Cl. CPC H04B 1/40; H03H 7/42; H04L 25/0272

(57) ABSTRACT

The present disclosure provides a power processing circuit, comprising at least one stage of power processing circuits. Each stage of the at least one stage of power processing circuits includes at least one set of power processing sub-circuits; each set of the at least one set of power processing sub-circuits includes a first differential signal port, N second differential signal ports, and a power processing unit connected between the first differential signal port and the N second differential signal ports. The power processing unit includes N pairs of differential coupling lines, where N≥2. In each stage of power processing circuits, a positive port and a negative port of at least one second differential signal port are connected to a positive coupling line and a negative coupling line, respectively, of different pairs of differential coupling lines.

### CROSS REFERENCE TO RELATED APPLICATIONS

This application is a continuation of International Application No. PCT/CN2024/128327, filed on Oct. 30, 2024, which claims priority to Chinese Patent Application No. 202410280779.0, filed on Mar. 12, 2024, the entire contents of each of which are incorporated herein by reference.

### TECHNICAL FIELD

The present disclosure relates to the field of radiofrequency and microwave, and in particular, to a power processing circuit.

### BACKGROUND

Power dividers are widely used in the field of wireless communication. A power divider divides a single signal into two or more signals of equal amplitude and phase, or it can combine two or more signals of equal amplitude and phase into a single signal. The power divider is used, for example, in combiners in low-earth orbit satellite communication or millimeter-wave communication systems. A bandwidth of the power divider affects the operating frequency of its system, in-band insertion loss impacts the transmitted power of wireless communication signals, and isolation directly affects the interference between communication signals.

In modern communication systems, power dividers and/or combiners, as important radio frequency (RF) components, are required to have wide bandwidth, low insertion loss, and high isolation. Commonly used power dividers and/or combiners have three implementation manners. The first manner uses lumped elements, such as capacitors and inductors, to build the power divider and/or combiner. This type is difficult to implement at high frequencies and has a relatively narrow bandwidth. The second manner uses distributed transmission lines, such as the Wilkinson power divider. However, this type of power divider faces challenges in balancing size and broadband performance. The third manner uses waveguides or dielectric integrated waveguides, which offer better performance but are difficult to miniaturize, making it challenging to achieve high integration and limited in practical applications.

The transmission link in modern communication systems requires high operating bandwidth, output power, and efficiency, meaning that power dividers/combiners need to have high bandwidth, low insertion loss, and high isolation. The receiving link needs to have high operating bandwidth, low noise, and high crosstalk suppression. However, the existing implementations of power dividers and/or combiners cannot simultaneously satisfy the requirements of modern communication systems for both the transmission and receiving links.

Therefore, it is desired to provide a power processing circuit that can further improve isolation while simultaneously addressing the requirements of both the transmission link and the receiving link.

### SUMMARY

The purpose of the present disclosure is to provide a power processing circuit that can further improve isolation while simultaneously addressing the requirements of both a transmitter link and a receiver link.

One or more embodiments of the present disclosure may provide a power processing circuit, comprising at least one stage of power processing circuits. Each stage of the at least one stage of power processing circuits may include at least one set of power processing sub-circuits; each set of the at least one set of power processing sub-circuits may include a first differential signal port, N second differential signal ports, and a power processing unit connected between the first differential signal port and the N second differential signal ports. The power processing unit may include N pairs of differential coupling lines, where N≥2; and in each stage of power processing circuits, a positive port and a negative port of at least one second differential signal port may be connected to a positive coupling line and a negative coupling line, respectively, of different pairs of differential coupling lines.

In some embodiments, in each stage of power processing circuits, a positive port and a negative port of at least one second differential signal port being connected to a positive coupling line and a negative coupling line, respectively, of different pairs of differential coupling lines includes: a positive port and a negative port of each of the at least one second differential signal port may be connected to the positive coupling line and the negative coupling line, respectively, of the different pairs of differential coupling lines.

In some embodiments, in each stage of power processing circuits, a positive port and a negative port of at least one second differential signal port being connected to a positive coupling line and a negative coupling line, respectively, of different pairs of differential coupling lines includes: the positive port and the negative port of the at least one second differential signal port may be connected to a positive coupling line and a negative coupling line, respectively, of different pairs of differential coupling lines in different sets of power processing sub-circuits in the at least one set of power processing sub-circuits.

In some embodiments, each stage of power processing circuits may include an isolation circuit, the isolation circuit may be arranged between ports with same polarity of different second differential signal ports in each stage of power processing circuits.

In some embodiments, the isolation circuit may be arranged between ports with same polarity of different second differential signal ports of a same set of power processing sub-circuits.

In some embodiments, the isolation circuit may further be arranged between ports with same polarity of different second differential signal ports in different sets of power processing sub-circuits.

In some embodiments, the isolation circuit may include an isolation resistor, or an isolation resistor and a capacitor that are connected in parallel.

In some embodiments, in each set of power processing sub-circuits, a positive port of the first differential signal port may be connected to a positive coupling line of a first pair of differential coupling lines, a negative port of the first differential signal port may be connected to a negative coupling line of an N-th pair of differential coupling lines, and a negative coupling line of an i-th pair of differential coupling lines may be connected to a positive coupling line of an (i+1)-th pair of differential coupling lines, where 1≤i<N.

In some embodiments, a negative coupling line of an i-th pair of differential coupling lines being connected to a positive coupling line of an (i+1)-th pair of differential coupling lines may include: the negative coupling line of the i-th pair of differential coupling lines may be connected to the positive coupling line of the (i+1)-th pair of differential coupling lines in series.

In some embodiments, the power processing circuit may be a power divider.

In some embodiments, in each set of power processing sub-circuits, the first differential signal port may serve as a differential signal input end and the second differential signal ports may serve as differential signal output ends.

In some embodiments, the power processing circuit may be a combiner.

In some embodiments, in each set of power processing sub-circuits, the first differential signal port serves as a differential signal output end and the second differential signal port may serve as differential signal input ends.

In some embodiments, at least one first differential signal port may be connected to a balun circuit.

In some embodiments, the at least one second differential signal port is connected to a balun circuit.

In some embodiments, a length of each of the differential coupling lines may be less than one-quarter of a wavelength of an electromagnetic wave at an operating center frequency.

In some embodiments, in a case where an upper stage of power processing circuits is connected to a lower stage of power processing circuits, at least one second differential signal port in the upper stage of power processing circuits may be connected to at least one first differential signal port in the lower stage of power processing circuits.

### BRIEF DESCRIPTION OF THE DRAWINGS

In order to more clearly illustrate the technical solutions in the embodiments of the present disclosure or the prior art, the accompanying drawings that need to be used in the embodiments will be briefly introduced in the following, and it will be obvious that the accompanying drawings in the following descriptions are only some embodiments of the present disclosure, and for those of ordinary skill in the art, other drawings can be obtained based on these drawings without creative labor.

FIG. 1 is a schematic diagram illustrating an exemplary structure of a power processing circuit in Embodiment 1 according to the present disclosure;

FIG. 2 is a schematic diagram illustrating an exemplary structure of the power processing circuit in Embodiment 1 in a power divider operating mode according to the present disclosure;

FIG. 3 is a schematic diagram illustrating an exemplary structure of the power processing circuit in Embodiment 1 in a combiner operating mode according to the present disclosure;

FIG. 4 is a schematic diagram illustrating an exemplary structure of a power processing circuit in Embodiment 2 according to the present disclosure;

FIG. 5 is a schematic diagram illustrating an exemplary structure of a power processing circuit in Embodiment 3 according to the present disclosure;

FIG. 6 is a schematic diagram illustrating an exemplary structure of a power processing circuit in Embodiment 4 according to the present disclosure;

FIG. 7 is a schematic diagram illustrating an exemplary structure of a power processing circuit in Embodiment 5 according to the present disclosure;

FIG. 8 is a schematic diagram illustrating an exemplary structure of a power processing circuit in Embodiment 6 according to the present disclosure;

FIG. 9 is a schematic diagram illustrating an exemplary structure of a multi-stage power processing circuit in Embodiment 7 according to the present disclosure;

FIG. 10 is a schematic diagram illustrating an exemplary structure of a multi-stage power processing circuit in Embodiment 8 according to the present disclosure;

FIG. 11 is a schematic diagram illustrating an exemplary structure of a multi-stage power processing circuit in Embodiment 9 according to the present disclosure;

FIG. 12 is a schematic diagram illustrating a principle of a circuit in the prior art according to some embodiments of the present disclosure;

FIG. 13 is a diagram illustrating isolation test results between ports of the circuit in FIG. 12 in the prior art according to some embodiments of the present disclosure;

FIG. 14 is a schematic diagram illustrating a principle of the power processing circuit in Embodiment 1 according to the present disclosure; and

FIG. 15 is a diagram illustrating isolation test results between ports of the power processing circuit in Embodiment 1 according to the present disclosure.

### DETAILED DESCRIPTION

In order to make the purpose, technical solutions, and advantages of the present disclosure clearer, technical solutions in the embodiments of the present disclosure will be described clearly and completely in the following in conjunction with the accompanying drawings in the embodiments of the present disclosure, and it is clear that the embodiments described are only embodiments of only a part of the embodiments of the present disclosure, and not all of the embodiments. Based on the embodiments in the present disclosure, all other embodiments obtained by a person of ordinary skill in the art without creative labor fall within the scope of protection of the present disclosure.

Embodiments of the present disclosure provide a power processing circuit, comprising at least one stage of power processing circuits. Each stage of the at least one stage of power processing circuits may include at least one set of power processing sub-circuits. Each set of the at least one set of power processing sub-circuits may include a first differential signal port, N second differential signal ports, and a power processing unit connected between the first differential signal port and the N second differential signal ports. The power processing unit may include N pairs of differential coupling lines, where N≥2. In each stage of power processing circuits, a positive port and a negative port of at least one second differential signal port may be connected to a positive coupling line and a negative coupling line of different pairs of differential coupling lines, respectively.

The power processing circuit refers to a circuit that processes signal power. In some embodiments, the power processing circuit includes one or more stages of power processing circuit. A count of stages of power processing circuit may be set according to actual needs.

In some embodiments, each stage of power processing circuits includes one or more sets of power processing sub-circuits. The power processing sub-circuit refers to a circuit that processes a portion of signal power. A count of sets of power processing sub-circuits may be set according to actual needs.

The second differential signal port may include a positive port and a negative port.

In some embodiments, a count of the second differential signal ports in each set of power processing sub-circuits is denoted by N, where N is an integer greater than or equal to 2. One second differential signal port may correspond to a pair of differential coupling lines, and N may also represent a count of pairs of differential coupling lines.

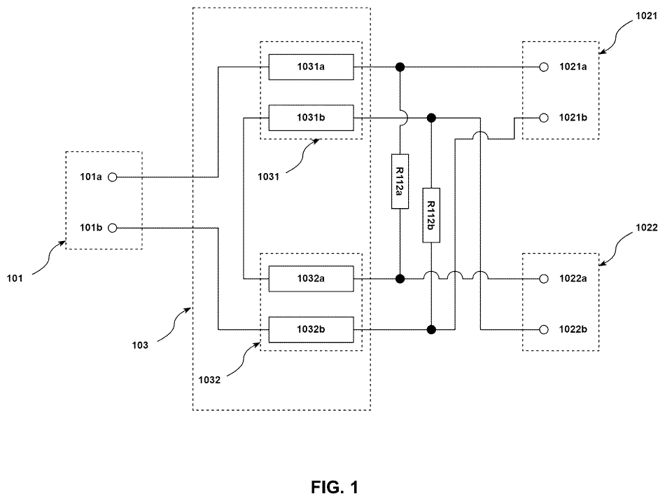

In some embodiments, in each stage of power processing circuits, a positive port and a negative port of at least one second differential signal ports are connected to a positive coupling line and a negative coupling line, respectively, of different pairs of differential coupling lines. For example, as shown in FIG. 1, a positive port and a negative port of each of two second differential signal ports are respectively connected to a positive coupling line and a negative coupling line, respectively, of different pairs of differential coupling lines. As another example, as shown in FIG. 6, a positive port and a negative port of one of second differential signal ports are connected to a positive coupling line and a negative coupling line of a same pair of differential coupling lines, while a positive port and a negative port of each of other two second differential signal ports are connected to a positive coupling line and a negative coupling line of different pairs of differential coupling lines, respectively. Related content can be found in the descriptions of FIG. 1 and FIG. 6 and the related descriptions thereof.

In some embodiments, a positive port and a negative port of each second differential signal port of the at least one second differential signal port are connected to a positive coupling line and a negative coupling line of different pairs of differential coupling lines, respectively. For example, the power processing circuit includes a plurality of second differential signal ports, and a positive port and a negative port of each of the plurality of second differential signal ports are connected to a positive coupling line and a negative coupling line, respectively, of different pairs of differential coupling lines.

For more content about the positive port and the negative port of each second differential signal port being connected to a positive coupling line and a negative coupling line, respectively, of different pairs of differential coupling lines, please refer to FIG. 1 to FIG. 5 and the related descriptions in the following embodiment.

The power processing unit refers to a component that is used to process power of an input signal.

The differential coupling line refers to a transmission line used to transmit a signal. In some embodiments, the differential coupling line includes the positive coupling line and the negative coupling line. The positive coupling line may be a wire that transmits a positive voltage of a signal. The negative coupling line may be a wire that transmits a negative voltage of the signal.

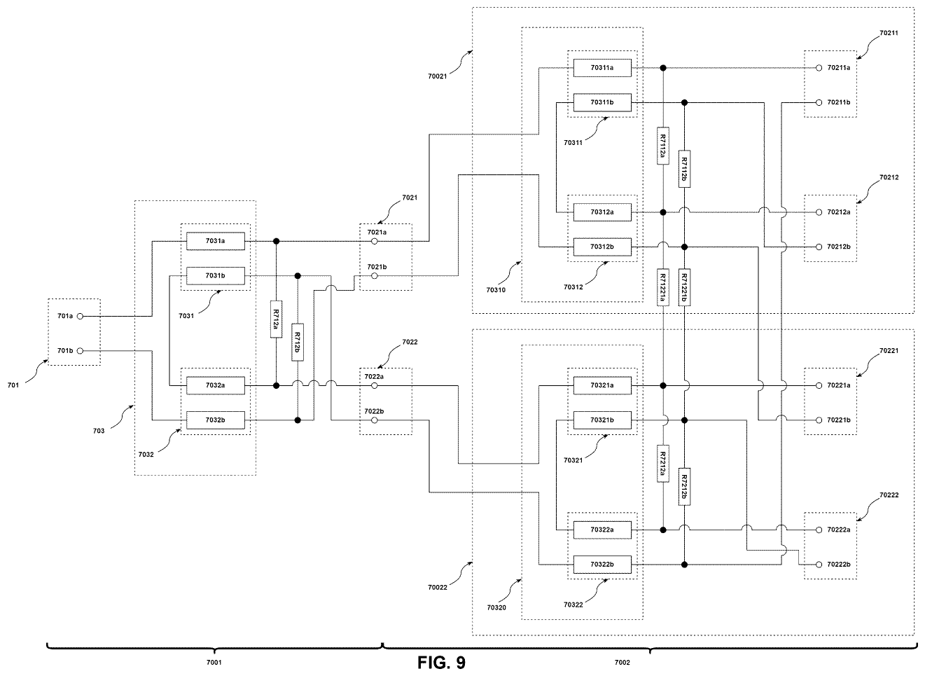

In some embodiments, a positive port and a negative port of at least one second differential signal port are connected to a positive coupling line and a negative coupling line, respectively, of different pairs of differential coupling lines. The positive coupling line and the negative coupling line of different pairs of differential coupling lines may belong to different sets of power processing sub-circuits of at least one set of power processing sub-circuits. For more information about the positive coupling line and the negative coupling line of different pairs of differential coupling lines belonging to different sets of power processing sub-circuits of at least one set of power processing sub-circuits, please refer to FIG. 9 and the related descriptions thereof.

In some embodiments, each stage of power processing circuits includes an isolation circuit. The isolation circuit may be arranged between ports with same polarity of different second differential signal ports in each stage of power processing circuits. The ports with same polarity may be ports with same electrodes. More information about the ports with same polarity can be found in FIG. 1 and the related descriptions thereof.

The isolation circuit may be a circuit for isolating a signal. In some embodiments, the isolation circuit includes an isolation resistor, or an isolation resistor and a capacitor that are connected in parallel, or the like. The isolation circuit may also include any other feasible structures, and specific structures may be set according to actual needs.

In some embodiments, the isolation circuit is arranged between ports with same polarity of different second differential signal ports of a same set of power processing sub-circuits.

In some embodiments, the isolation circuit is also arranged between ports with same polarity of different second differential signal ports of different sets of power processing sub-circuits.

More information about the isolation circuit can be found in Embodiment 1 to Embodiment 10 and the related descriptions thereof.

In some embodiments, in each set of power processing sub-circuits, a positive port of a first differential signal port is connected to a positive coupling line of a first pair of differential coupling lines, and a negative port of the first differential signal port is connected to a negative coupling line of an N-th pair of differential coupling lines, and a negative coupling line of an i-th pair of differential coupling lines is connected to a positive coupling line of an (i+1)-th pair of differential coupling lines, where 1≤i.

In some embodiments, the negative coupling line of the i-th pair of differential coupling lines is connected to the positive coupling line of the (i+1)-th pair of differential coupling lines in series.

In some embodiments, the power processing circuit is a power divider. The power divider may be a power divider.

In some embodiments, the power divider divides a signal into a plurality of equal or unequal signal components. For example, when the power processing circuit serves as the power divider, in each set of power processing sub-circuits, a first differential signal port serves as a differential signal input end and second differential signal ports serve as differential signal output ends.

In some embodiments, the power processing circuit is a combiner. The combiner may be a component used to combine signals.

In some embodiments, the combiner combines a plurality of equal or unequal signals into one signal. For example, when the power processing circuit serves as the combiner, in each set of power processing sub-circuits, a first differential signal port serves as a differential signal output end, and second differential signal ports serve as differential signal input ends.

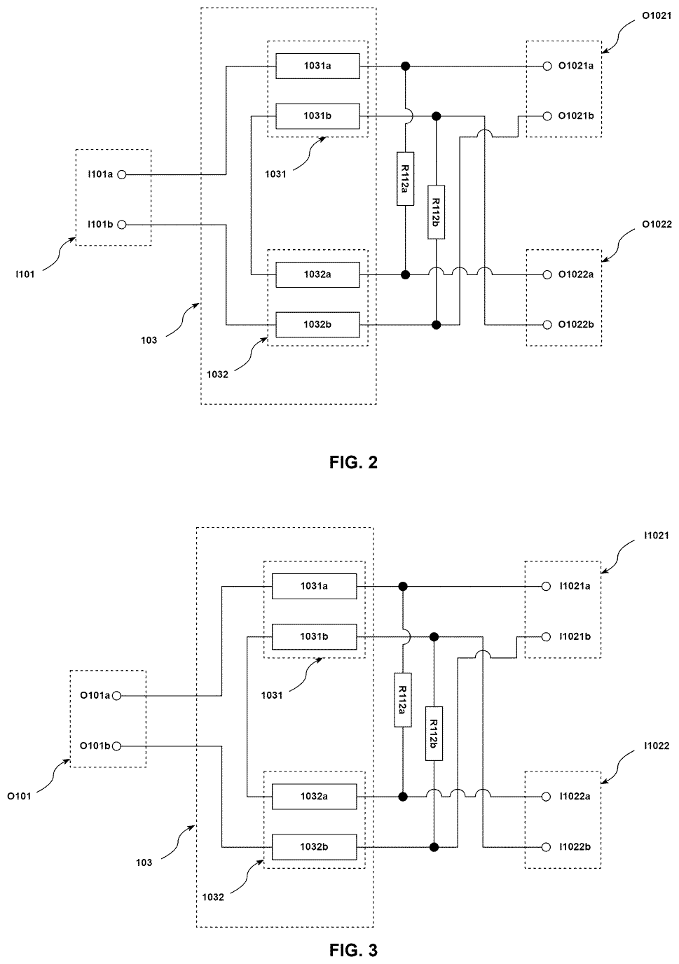

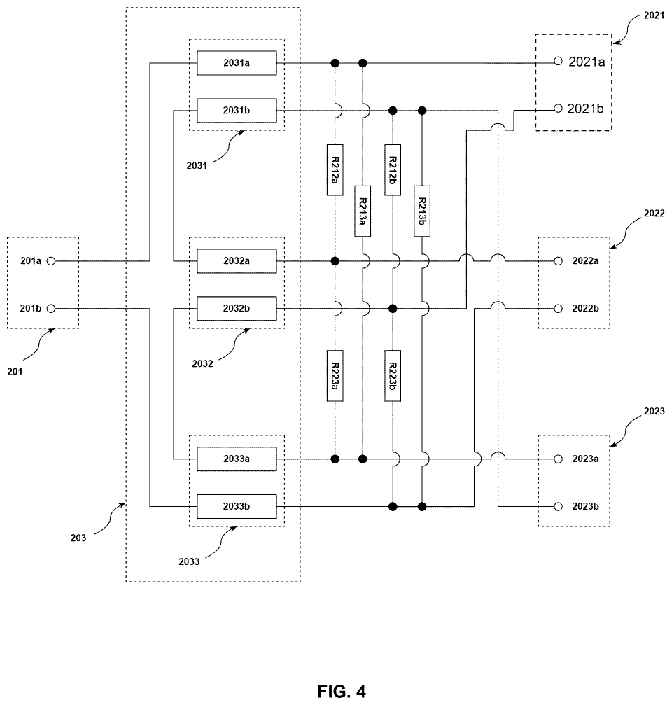

More information about the power divider and the combiner can be found in FIG. 2, FIG. 3, and the related descriptions thereof.

In some embodiments, at least one first differential signal port is connected to a balun circuit. The balun circuit may be a circuit that converts a signal from a single-ended signal to a differential signal.

In some embodiments, at least one second differential signal port is connected to the balun circuit.

In some embodiments, a length of the differential coupling line is less than one-quarter of a wavelength of an electromagnetic wave at an operating center frequency. In some embodiments, the length of the differential coupling line is set according to actual needs.

In some embodiments, in a case where an upper stage of power processing circuits is connected to a lower stage of power processing circuits, at least one second differential signal port in the upper stage of power processing circuits is connected to at least one first differential signal port in the lower stage of power processing circuits.

In some embodiments of the present disclosure, an isolation of the entire power processing circuit can be further improved through the power processing circuit.

The following illustrates in detail the specific implementation of the present disclosure based on a plurality of embodiments in which there is only one stage of power processing circuits and a plurality of embodiments in which there are two stages of power processing circuit.

It should be noted that the following embodiments are some more specific illustrations of embodiments related to some of the above embodiments. Some of these embodiments may also be replaced or combined with corresponding elements in other embodiments to form new embodiments. It should be understood that the following embodiments are provided for the purpose of better interpreting the present disclosure, and are not intended to be limiting.

### Embodiment 1

FIG. 1 is a schematic diagram illustrating an exemplary structure of a power processing circuit in Embodiment 1 according to the present disclosure.

In some embodiments, FIG. 1 shows a set of power processing sub-circuits included in one stage of at least one stage of power processing circuits.

As shown in FIG. 1, a count N of second differential signal ports is 2. As shown in FIG. 1, the power processing sub-circuit includes one first differential signal port 101, two second differential signal ports 1021 and 1022, and a power processing unit 103 connected between the first differential signal port 101 and the two second differential signal ports 1021 and 1022.

In some embodiments, the first differential signal port 101 includes a positive port 101a and a negative port 101b.

In some embodiments, the second differential signal port 1021 includes a positive port 1021a and a negative port 1021b. In some embodiments, the second differential signal port 1022 includes a positive port 1022a and a negative port 1022b.

In some embodiments, when the count N of the second differential signal ports is 2, the power processing unit 103 includes 2 pairs of differential coupling lines 1031 and 1032.

In some embodiments, the first pair of differential coupling lines 1031 includes a positive coupling line 1031a and a negative coupling line 1031b, as shown in FIG. 1. The second pair of differential coupling lines 1032 includes a positive coupling line 1032a and a negative coupling line 1032b.

In some embodiments, the positive port 101a of the first differential signal port 101 is connected to the positive coupling line 1031a of the first pair of differential coupling lines 1031, as shown in FIG. 1. The negative port 101b of the first differential signal port 101 is connected to the negative coupling line 1032b of the second pair of differential coupling lines 1032. The negative coupling line 1031b of the first pair of differential coupling lines 1031 is connected, e.g., in series, to the positive coupling line 1032a of the second pair of differential coupling lines 1032.

In some embodiments, as shown in FIG. 1, the positive port 1021a of the second differential signal port 1021 is connected to the positive coupling line 1031a of the first pair of differential coupling lines 1031, and the second differential signal port 1021b of the second differential signal port 1021 is connected to the negative coupling line 1032b of the second pair of differential coupling lines 1032.

In some embodiments, as shown in FIG. 1, the positive port 1022a of the second differential signal port 1022 is connected to the positive coupling line 1032a of the second pair of differential coupling lines 1032, and the negative port 1022b of the second differential signal port 1022 is connected to the negative coupling line 1031b of the first pair of differential coupling lines 1031.

In some embodiments, the positive port 1021a and the negative port 1021b of the second differential signal port 1021 are connected to a positive coupling line and a negative coupling line, respectively, of different pairs of differential coupling lines, as shown in FIG. 1. The positive port 1022a and the negative port 1022b of the second differential signal port 1022 are also connected to a positive coupling line and a negative coupling line, respectively, of different pairs of differential coupling lines.

In some embodiments, each stage of power processing circuits further includes an isolation circuit. The isolation circuit is arranged between ports with same polarity of different second differential signal ports in each stage of power processing circuits.

For example, as shown in FIG. 1, isolation resistors serving as isolation circuits are arranged between ports with same polarity of different second differential signal ports. Merely by way of example, a total of 2 isolation resistors R112a and R112b are arranged in FIG. 1. The isolation resistor R112a is arranged between the positive port 1021a of the second differential signal port 1021 and the positive port 1022a of the second differential signal port 1022. The isolation resistor R112b is arranged between the negative port 1021b of the second differential signal port 1021 and the negative port 1022b of the second differential signal port 1022.

In some embodiments of the present disclosure, an isolation of the power processing circuit can be further enhanced by setting the isolation circuit and enabling the positive port and the negative port of the at least one second differential signal port to be connected to the positive coupling line and the negative coupling line, respectively, of different pairs of differential coupling lines.

In some embodiments, in addition to using the isolation resistor as the isolation circuit, it can also be replaced by an isolation resistor and a capacitor that are connected in parallel. For example, a capacitor may be connected to the isolation resistor R112a in parallel.

FIG. 2 is a schematic diagram illustrating an exemplary structure of the power processing circuit in Embodiment 1 in a power divider operating mode according to the present disclosure.

In some embodiments, in each set of power processing sub-circuits, a first differential signal port serves as a differential signal input end and the second differential signal ports serve as differential signal output ends.

In some embodiments, the positive port 101a and the negative port 101b of the first differential signal port 101 in FIG. 1 are represented in FIG. 2 by a positive input end I101a and a negative input end I101b of a differential signal input end I101, respectively. The positive port 1021a and the negative port 1021b of the second differential signal port 1021 in FIG. 1 are represented in FIG. 2 by a positive output end O1021a and a negative output end O1021b of a differential signal output end O1021b, respectively. The positive port 1022a and the negative port 1022b of the second differential signal port 1022 in FIG. 1 are represented in FIG. 2 by a positive output end O1022a and a negative output end O1022b of a differential signal output end O1022b, respectively. Other circuit components in FIG. 2 are the same as those labeled the same in FIG. 1, and will not be repeated herein.

FIG. 3 is a schematic diagram illustrating an exemplary structure of a power processing circuit in Embodiment 1 in a combiner operating mode according to the present disclosure.

In some embodiments, in each set of power processing sub-circuits, the first differential signal port serves as a differential signal output end of a combined signal and the second differential signal ports serve as differential signal input ends of the combined signal.

In some embodiments, the positive port 101a and the negative port 101b of the first differential signal port 101 in FIG. 1 are represented in FIG. 3 by a positive output end O101a and a negative output end O101b, respectively, of a differential signal output end O101. The positive port 1021a and the negative port 1021b of the second differential signal port 1021 in FIG. 1 are represented in FIG. 3 by a positive input end I1021a and a negative input end I1021b, respectively, of a differential signal input end I1021. The positive port 1022a and the negative port 1022b of the second differential signal port 1022 in FIG. 1 are represented in FIG. 3 by a positive input end I1022a and a negative input end I1022b, respectively, of a differential signal output port I1022. Other circuit components are the same as those labeled the same in FIG. 1, and will not be repeated herein.

In some embodiments, the power processing circuit provided in Embodiment 1 can optimize in-band insertion loss, return loss, isolation, and other parameters by adjusting an electrical length differential coupling lines, a common-mode impedance (Ze), a differential-mode impedance (Zo), an isolation circuit, or the like.

In some embodiments, the power processing circuit provided in Embodiment 1 does not require the use of a quarter-wavelength coupling line, allowing a length of a differential coupling line to be smaller than one-quarter of a wavelength of an electromagnetic wave at an operating center frequency. This reduces an overall size of the power processing circuit, increases integration, and improves insertion loss performance. By adjusting the electrical length of the differential coupling line, the common-mode impedance (Ze), and the differential-mode impedance (Zo), an operating bandwidth can be controlled.

In addition, it should be noted that in this embodiment and the other embodiments described below, the terms “positive” and “negative” are relative concepts, and they may simply indicate “inverted” or “out-of-phase” between signals of corresponding ports. If a “positive” port and a “negative” port are swapped, the circuit in this embodiment can still function normally, and such modifications are still within the scope of protection of the present disclosure.

### Embodiment 2

FIG. 4 is a schematic diagram illustrating an exemplary structure of a power processing circuit in Embodiment 2 according to the present disclosure. In some embodiments, a count N of a second differential signal port is 3. As shown in FIG. 4, the power processing circuit includes a first differential signal port 201, three second differential signal ports 2021, 2022, and 2023, and a power processing unit 203 connected between the first differential signal port 201 and the three second differential signal ports 2021, 2022, and 2023.

In some embodiments, the first differential signal port 201 includes a positive port 201a and a negative port 201b, as shown in FIG. 4.

In some embodiments, the second differential signal port 2021 includes a positive port 2021a and a negative port 2021b, as shown in FIG. 4. The second differential signal port 2022 includes a positive port 2022a and a negative port 2022b, as shown in FIG. 4. The second differential signal port 2023 includes a positive port 2023a and a negative port 2023b, as shown in FIG. 4.

In some embodiments, when the count N of the second differential signal ports is 3, the power processing unit 203 includes three pairs of differential coupling lines 2031, 2032, and 2033, respectively.

In some embodiments, as shown in FIG. 4, the first pair of differential coupling lines 2031 includes a positive coupling line 2031a and a negative coupling line 2031b. The second pair of differential coupling lines 2032 includes a positive coupling line 2032a and a negative coupling line 2032b. The third pair of differential coupling lines 2033 includes a positive coupling line 2033a and a negative coupling line 2033b.

In some embodiments, the positive port 201a of the first differential signal port 201 is connected to the positive coupling line 2031a of the first pair of differential coupling lines 2031, as shown in FIG. 4. The negative port 201b of the first differential signal port 201 is connected to the negative coupling line 2033b of the third pair of differential coupling lines 2033. The negative coupling line 2031b of the first pair of differential coupling lines 2031 is connected, e.g., in series, to the positive coupling line 2032a of the second pair of differential coupling lines 2032.

In some embodiments, the negative coupling line 2032b of the second pair of differential coupling lines 2032 is connected, e.g., in series, to the positive coupling line 2033a of the third pair of differential coupling lines 2033, as shown in FIG. 4.

In some embodiments, the positive port 2021a of the second differential signal port 2021 is connected to the positive coupling line 2031a of the first pair of differential coupling lines 2031, as shown in FIG. 4. The negative port 2021b of the second differential signal port 2021 is connected to the negative coupling line 2032b of the second pair of differential coupling lines 2032.

In some embodiments, the positive port 2022a of the second differential signal port 2022 is connected to the positive coupling line 2032a of the second pair of differential coupling lines 2032, as shown in FIG. 4. The negative port 2022b of the second differential signal port 2022 is connected to the negative coupling line 2033b of the third pair of differential coupling lines 2033.

In some embodiments, the positive port 2023a of the second differential signal port 2023 is connected to the positive coupling line 2033a of the third pair of differential coupling lines 2033, as shown in FIG. 4. The negative port 2023b of the second differential signal port 2023 is connected to the negative coupling line 2031b of the first pair of differential coupling lines 2031.

In some embodiments, as shown in FIG. 4, a positive port and a negative port of each second differential signal port are connected to a positive coupling line and a negative coupling line of different pairs of differential coupling lines, respectively.

In some embodiments, each stage of power processing circuits further includes an isolation circuit. The isolation circuit is arranged between ports with same polarity of different second differential signal ports in each stage of power processing circuits.

For example, an isolation resistor serving as an isolation circuit is arranged between ports with same polarity of different second differential signal ports, as shown in FIG. 4. Merely by way of example, a total of six isolation resistors R212a, R212b, R223a, R223b, R213a, and R213b are arranged in FIG. 4. The isolation resistor R212a is arranged between the positive port 2021a of the second differential signal port 2021 and the positive port 2022a of the second differential signal port 2022. The isolation resistor R223b is arranged between the negative port 2021b of the second differential signal port 2021 and the negative port 2022b of the second differential signal port 2022. The isolation resistor R223a is arranged between the positive port 2022a of the second differential signal port 2022 and the positive port 2023a of the second differential signal port 2023, the isolation resistor R213b is arranged between the negative port 2022b of the second differential signal port 2022 and the negative port 2023b of the second differential signal port 2023. The isolation resistor R213a is arranged between the positive port 2021a of the second differential signal port 2021 and the positive port 2023a of the second differential signal port 2023. The isolation resistor R212b is arranged between the negative port 2021b of the second differential signal port 2021 and the negative port 2023b of the second differential signal port 2023.

In some embodiments of the present disclosure, by setting the isolation circuit, and connecting a positive port and a negative port of at least one second differential signal port to a positive coupling line and a negative coupling line, respectively, of different pairs of differential coupling lines, isolation of the power processing circuit can be further enhanced.

In some embodiments, Embodiment 2 is similar to Embodiment 1 in that isolation can be optimized by, for example, varying an electrical length of a differential coupling line. There is no need to use a quarter-wavelength coupling line, which reduces the overall size of the entire circuit, increases integration, and improves insertion loss performance. More information can be found in Embodiment 1 and the related descriptions thereof.

In some embodiments, if the first differential signal port of the circuit in Embodiment 2 is used as a differential signal input end and the second differential signal ports are used as differential signal output ends, the entire circuit is equivalent to a power divider.

In some embodiments, if the first differential signal port of the circuit in Embodiment 2 is used as a differential signal output end and the second differential signal ports are used as differential signal input ends, the entire circuit is equivalent to a combiner.

### Embodiment 3

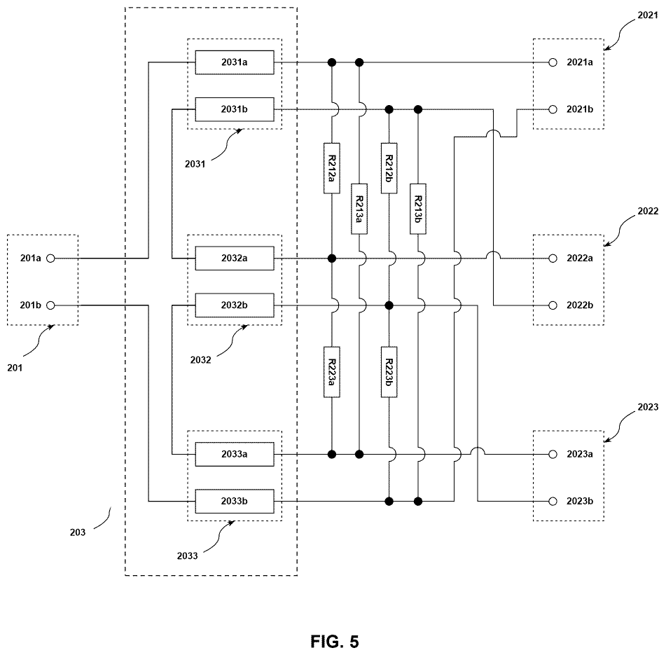

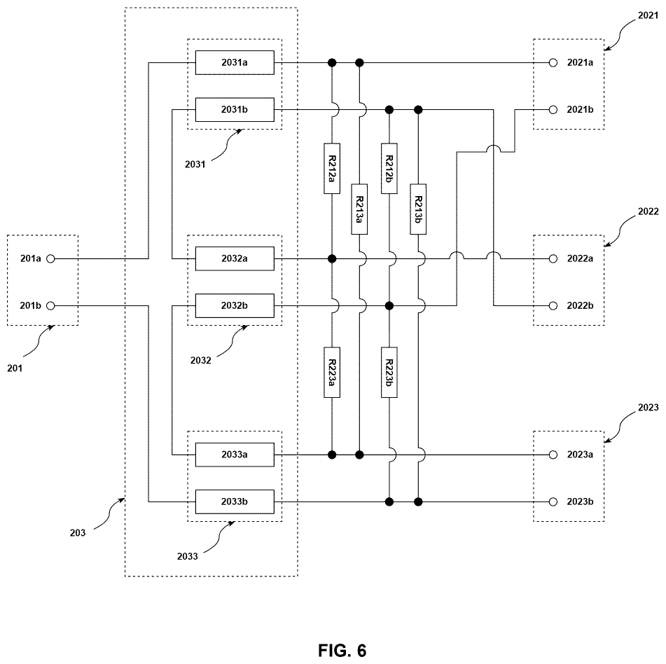

FIG. 5 is a schematic diagram illustrating an exemplary structure of a power processing circuit in Embodiment 3 according to the present disclosure. A difference between FIG. 4 and FIG. 5 is mainly as follows.

As shown in FIG. 5, a specific implementation of a positive port and a negative port of each second differential signal port of at least one second differential signal port being connected to a positive coupling line and a negative coupling line, respectively, of different pairs of differential coupling lines is differently. Components labeled in FIG. 5 are the same as those labeled in FIG. 4 and will not be repeated here.

In some embodiments, a difference between an embodiment illustrated in FIG. 5 and an embodiment illustrated in FIG. 4 is that, in FIG. 5, the negative port 2021b of the second differential signal port 2021 is connected to the negative coupling line 2033 of the third pair of differential coupling lines 2033b. The negative port 2022b of the second differential signal port 2022 is connected to the negative coupling line 2031b of the first pair of differential coupling lines 2031. The negative port 2023b of the second differential signal port 2023 is connected to the negative coupling line 2032b of the second pair of differential coupling lines 2032. Correspondingly, an isolation resistor R213b is arranged between the negative port 2021b of the second differential signal port 2021 and the negative port 2022b of the second differential signal port 2022. The isolation resistor R212b is arranged between the negative port 2022b of the second differential signal port 2022 and the negative port 2023b of the second differential signal port 2023. The isolation resistor R223b is arranged between the negative port 2021b of the second differential signal port 2021 and the negative port 2023b of the second differential signal port 2023.

### Embodiment 4

FIG. 6 is a schematic diagram illustrating an exemplary structure of a power processing circuit in Embodiment 4 according to the present disclosure.

As shown in FIG. 6, a difference between embodiments illustrated in FIG. 4 and FIG. 5 is that, in FIG. 6, for at least one second differential signal port, a positive port and a negative port of each second differential signal port are not necessarily connected to a positive coupling line and a negative coupling line, respectively, of different pairs of differential coupling lines. Components labeled in FIG. 6 are the same as those labeled in FIG. 4 and FIG. 5, and will not be repeated here.

In some embodiments, the positive port 2021a of the second differential signal port 2021 is connected to the positive coupling line 2031a of the first pair of differential coupling lines 2031, as shown in FIG. 6. The negative port 2021b of the second differential signal port 2021 is connected to the negative coupling line 2032b of the second pair of differential coupling lines 2032.

In some embodiments, as shown in FIG. 6, the positive port 2022a of the second differential signal port 2022 is connected to the positive coupling line 2032a of the second pair of differential coupling lines 2032. The negative port 2022b of the second differential signal port 2022 is connected to the negative coupling line 2031b of the first pair of differential coupling lines 2031.

In some embodiments, as shown in FIG. 6, the positive port 2023a of the second differential signal port 2023 is connected to the positive coupling line 2033a of the third pair of differential coupling lines 2033. The negative port 2023b of the second differential signal port 2023 is connected to the negative coupling line 2033b of the third pair of differential coupling lines 2033.

In some embodiments, the isolation resistor R212b is arranged between the negative port 2021b of the second differential signal port 2021 and the negative port 2022b of the second differential signal port 2022, as shown in FIG. 6. The isolation resistor R213b is arranged between the negative port 2022b of the second differential signal port 2022 and the negative port 2023b of the second differential signal port 2023. The isolation resistor R223b is arranged between the negative port 2021b of the second differential signal port 2021 and the negative port 2023b of the second differential signal port 2023.

In some embodiments, a positive port and a negative port of the second differential signal port 2023 are connected to a positive coupling line and a negative coupling line of a same pair of differential coupling lines, as shown in FIG. 6. The positive port and negative port of each of the other two second differential signal ports are respectively connected to a positive coupling line and a negative coupling line, respectively, of different pairs of differential coupling lines.

It will be appreciated that for a power processing circuit with three second differential signal ports, a second differential signal port whose positive port and negative port are connected to a positive coupling line and a negative coupling line of a same pair of differential coupling lines may be selected from any of the three second differential signal ports. The positive port and negative port of each of the other two second differential signal ports are connected to a positive coupling line and a negative coupling line, respectively, of different pairs of differential coupling lines.

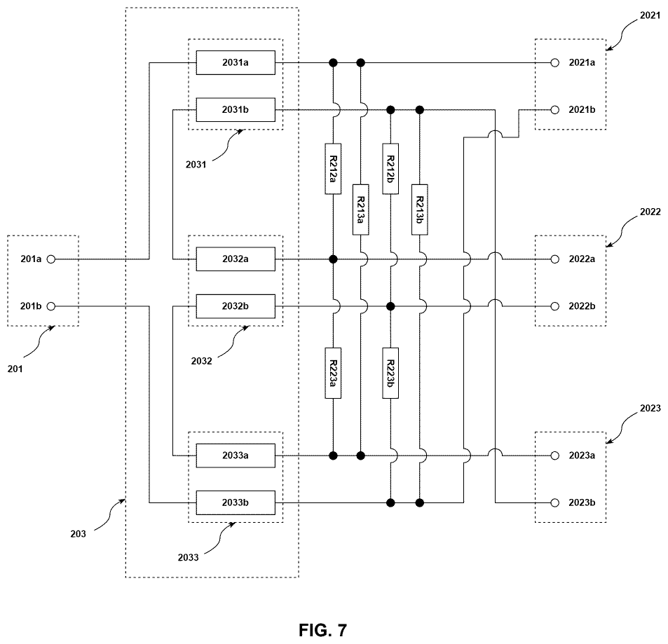

For example, a positive port and a negative port of the second differential signal port 2021 are connected to a positive coupling line and a negative coupling line of a same pair of differential coupling lines (e.g., the first pair of differential coupling lines 2021), while a positive port and a negative port of each of the other two second differential signal ports (i.e., the second differential signal port 2022 or the second differential signal port 2023) are connected to a positive coupling line a negative coupling line, respectively, of different pairs of differential coupling lines. More information about another power processing circuit with three second differential signal ports can be found in FIG. 7 and the related descriptions thereof.

### Embodiment 5

FIG. 7 is a schematic diagram illustrating an exemplary structure of a power processing circuit in Embodiment 5 according to the present disclosure.

In some embodiments, as shown in FIG. 7, the positive port 2022a and the negative port 2022b of the second differential signal port 2022 are connected to the positive coupling line 2032a and the negative coupling line 2032b of a same pair of differential coupling lines, such as the second pair of differential coupling lines 2023. The positive port and negative port of each of other two second differential signal ports (i.e., the second differential signal port 2021 or the second differential signal port 2023) are connected to a positive coupling line and a negative coupling line, respectively, of different pairs of differential coupling lines.

In some embodiments, the positive port 2021a of the second differential signal port 2021 is connected to the positive coupling line 2031a of the first pair of differential coupling lines 2031, as shown in FIG. 7. The negative port 2021b of the second differential signal port 2021 is connected to the negative coupling line 2033b of the third pair of differential coupling lines 2033.

In some embodiments, the positive port 2023a of the second differential signal port 2023 is connected to the positive coupling line 2033a of the third pair of differential coupling lines 2033, as shown in FIG. 7. The negative port 2023b of the second differential signal port 2023 is connected to the negative coupling line 2031b of the first pair of differential coupling lines 2031.

In some embodiments, the isolation resistor R223b is arranged between the negative port 2023b of the second differential signal port 2021 and the negative port 2022b of the second differential signal port 2022, as shown in FIG. 7. The isolation resistor R212b is arranged between the negative port 2022b of the second differential signal port 2022 and the negative port 2023b of the second differential signal port 2023. The isolation resistor R213b is arranged between the negative port 2021b of the second differential signal port 2021 and the negative port 2023b of the second differential signal port 2023.

### Embodiment 6

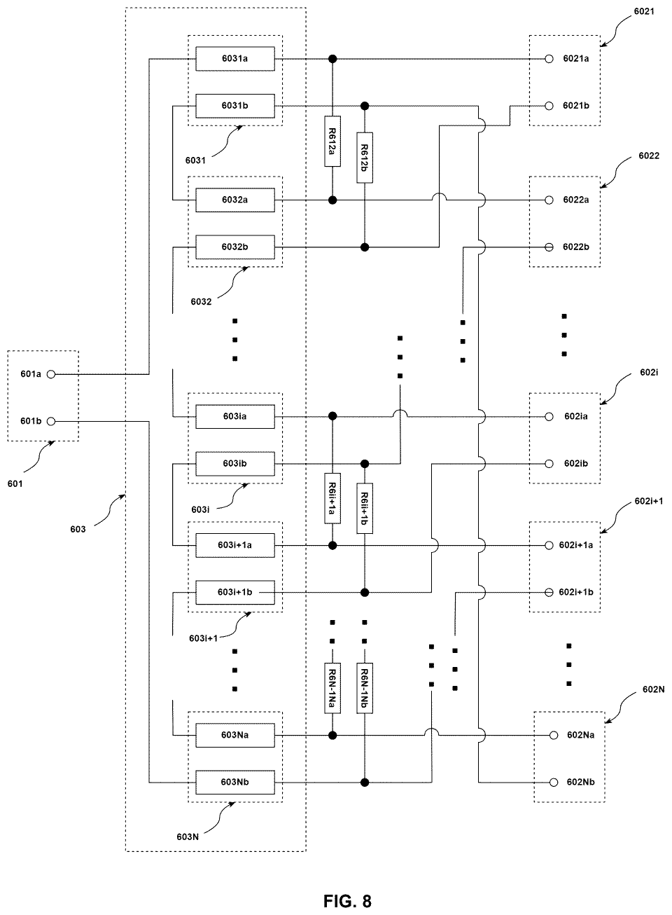

FIG. 8 is a schematic diagram illustrating an exemplary structure of a power processing circuit in Embodiment 6 according to the present disclosure.

In some embodiments, a count of second differential signal ports and a count of pairs of differential coupling lines in the power processing unit are set to N. N>2 and N is a positive integer. As shown in FIG. 8, the power processing circuit includes a first differential signal port 601, N second differential signal ports 6021 to 602N, and a power processing unit 603 connected between the first differential signal port 601, and the N second differential signal ports 6021 to 602N.

In some embodiments, the first differential signal port 601 includes a positive port 601a and a negative port 601b, as shown in FIG. 8. Each second differential signal port includes a positive port and a negative port.

In some embodiments, the second differential signal port 6021 includes a positive port 6021a and a negative port 6021b, as shown in FIG. 8. The second differential signal port 6022 includes a positive port 6022a and a negative port 6022b. In this order, the second differential signal port 602i includes a positive port 602ia and a negative port 602ib. The second differential signal port 602(i+1) includes a positive port 602(i+1)a and a negative port 602(i+1)b. The N-th differential signal port 602N includes a positive port 602Na and a negative port 602Nb.

In some embodiments, as shown in FIG. 8, the power processing unit 603 includes N pairs of differential coupling lines 6031 to 603N, respectively. Each pair of differential coupling lines includes a positive coupling line and a negative coupling line. For example, the first pair of differential coupling lines 6031 includes a positive coupling line 6031a and a negative coupling line 6031b. The second pair of differential coupling lines 6032 includes a positive coupling line 6032a and a negative coupling line 6032b. By analogy, the i-th pair of differential coupling lines 603i includes a positive coupling line 603ia and a negative coupling line 603ib. The (i+1)-th pair of differential coupling lines 603(i+1) includes a positive coupling line 603(i+1) a and a negative coupling line 603(i+1)b. The N-th pair of differential coupling lines 603N includes a positive coupling line 603Na and a negative coupling line 603Nb.

In some embodiments, in each set of power processing sub-circuits, the positive port 601a of the first differential signal port 601 is connected to the positive coupling line 6031a of the first pair of differential coupling lines 6031, as shown in FIG. 8. The negative port 601b of the first differential signal port 601 is connected to the negative coupling line 603Nb of the N-th pair of differential coupling lines 603N. The negative coupling line 603ib of the i-th pair of differential coupling lines 603i is connected, e.g., in series, to the positive coupling line 603(i+1)a of the (i+1)-th pair of differential coupling lines 603(i+1), where 1≤i<N.

In some embodiments, as shown in FIG. 8, a positive port and a negative port of at least one second differential signal port of the N second differential signal ports 6021 to 602N are connected to a positive coupling line and the negative coupling line, respectively, of different pairs of differential coupling lines. For example, a positive port and a negative port of each of at least two second differential signal ports of the N second differential signal ports 6021 to 602N are both connected to a positive coupling line and a negative coupling line, respectively, of different pairs of differential coupling lines.

In some embodiments, as shown in FIG. 8, a positive port and a negative port of each second differential signal port of the at least one second differential signal port of the N second differential signal ports 6021 to 602N are connected to a positive coupling line and a negative coupling line, respectively, of different pairs of differential coupling line.

In some embodiments, as shown in FIG. 8, the positive port 6021a and the negative port 6021b of the second differential signal port 6021 are connected to the positive coupling line 6031a of the first pair of differential coupling lines 6031 and the negative coupling line 6032b of the second pair of differential coupling lines 6032, respectively. In analogy, the positive port 602ia and the negative port 602ib of the second differential signal port 602i are connected to the positive coupling line 603ia of the i-th pair of differential coupling lines 603i and the negative coupling line 603(i+1)b of the (i+1)-th pair of differential coupling lines 603(i+1), where 1≤i.

In some embodiments, each stage of power processing circuits further includes an isolation circuit as shown in FIG. 8. The isolation circuit is arranged between ports with same polarity of different second differential signal ports.

For example, the isolation circuit is arranged between a positive port of an i-th second differential signal port and a positive port of a j-th second differential signal port. The isolation circuit is also arranged between a negative port of the i-th second differential signal port and a negative port of the j-th second differential signal port, where 1≤i<N, 1≤j<N, and i≠j. The isolation circuit may be realized using an isolation resistor, and may also be realized by an isolation resistor and a capacitor that are connected in parallel.

In some embodiments, Embodiment 6 is similar to Embodiment 1 in that an isolation can be enhanced by varying, for example, an electrical length of the differential coupling line. There is no need to use a quarter-wavelength coupling line, which reduces the overall size of the circuit, increases integration, and improves insertion loss performance. More information can be found in Embodiment 1 and the related descriptions thereof.

### Embodiment 7

FIG. 9 is a schematic diagram illustrating an exemplary structure of a multi-stage power processing circuit in Embodiment 7 according to the present disclosure.

As shown in FIG. 9, the multi-stage power processing circuit includes two stages of power processing circuit including a first stage of power processing circuits 7001 and a second stage of power processing circuits 7002.

In some embodiments, the first stage of power processing circuits 7001 is structured similarly to the power processing circuit illustrated in FIG. 1, as shown in FIG. 9. N in the first stage of power processing circuits 7001 may be selected as 2. The first stage of power processing circuits 7001 includes one first differential signal port 701, two second differential signal ports 7021 and 7022, and a power processing unit 703 connected between the first differential signal port 701 and the two second differential signal ports 7021 and 7022.

In some embodiments, as shown in FIG. 9, the first differential signal port 701 includes a positive port 701a and a negative port 701b. The second differential signal port 7021 includes a positive port 7021a and a negative port 7021b. The second differential signal port 7022 includes a positive port 7022a and a negative port 7022b.

In some embodiments, as shown in FIG. 9, the power processing unit 703 includes two pairs of differential coupling lines 7031 and 7032. The first pair of differential coupling lines 7031 includes a positive coupling line 7031a and a negative coupling line 7031b. The second pair of differential coupling lines 7032 includes a positive coupling line 7032a and a negative coupling line 7032b.

In some embodiments, the positive port 701a of the first differential signal port 701 is connected to the positive coupling line 7031a of the first pair of differential coupling lines 7031 of the power processing unit 703, as shown in FIG. 9. The negative port 701b of the first differential signal port 701 is connected to the negative coupling line 7032b of the second pair of differential coupling lines 7032 of the power processing unit 703. The negative coupling line 7031b of the first pair of differential coupling lines 7031 is connected, e.g., in series, to the positive coupling line 7032a of the second pair of differential coupling lines 7032.

In some embodiments, the positive port 7021a of the second differential signal port 7021 is connected to the positive coupling line 7031a of the first pair of differential coupling lines 7031, as shown in FIG. 9. The negative port 7021b of the second differential signal port 7021 is connected to the negative coupling line 7032b of the second pair of differential coupling lines 7032.

In some embodiments, the positive port 7022a of the second differential signal port 7022 is connected to the positive coupling line 7032a of the second pair of differential coupling lines 7032, as shown in FIG. 9. The negative port 7022b of the second differential signal port 7022 is connected to the negative coupling line 7031b of the first pair of differential coupling lines 7031.

In some embodiments, in the first stage of power processing circuits, the positive port 7021a and the negative port 7021b of the second differential signal port 7021 are connected to a positive coupling line and a negative coupling line, respectively, of different pairs of differential coupling lines. The positive port 7022a and the negative port 7022b of the second differential signal port 7022 are connected to a positive coupling line and a negative coupling line, respectively, of different pairs of differential coupling lines.

In some embodiments, the first stage of power processing circuits further includes an isolation circuit. The isolation circuit is arranged between ports with same polarity of different second differential signal ports.

As shown in FIG. 9, in the first stage of power processing circuits, an isolation resistor serving as an isolation circuit is arranged between ports with same polarity of different second differential signal ports.

In some embodiments, the first stage of power processing circuits is provided with two isolation resistors R712a and R712b. The isolation resistor R712a is arranged between the positive port 7021a of the second differential signal port 7021 and the positive port 7022a of the second differential signal port 7022. The isolation resistor R712b is arranged between the negative port 7021b of the second differential signal port 7021 and the negative port 7022b of the second differential signal port 7022.

In some embodiments of the present disclosure, by setting the isolation circuit between ports with same polarity of different second differential signal ports in a same set of power processing sub-circuits, an isolation between ports in the first stage of power processing circuits 7001 is further improved.

In some embodiments, as shown in FIG. 9, the second stage of power processing circuits 7002 is divided into two sets of power processing sub-circuits 70021 and 70022.

In some embodiments, N corresponding to the first set of power processing sub-circuits 70021 is selected to be 2, as shown in FIG. 9. The first set of power processing sub-circuits 70021 includes one first differential signal port. The first differential signal port is the same port or connected to the second differential signal port 7021 in the first stage of power processing circuits 7001. Merely by way of example, a positive port and a negative port of the first differential signal port of the first set of power processing sub-circuits 70021 are the same ports or connected with the positive port 7021a and the negative port 7021b of the second differential signal port 7021 of the first set of power processing circuits 7001. As shown in FIG. 9, the first differential signal port of the first set of power processing sub-circuits 70021 is marked with same reference numerals 7021a and 7021b as the positive port and negative port of the second differential signal port 7021 in the first stage of power processing circuits 7001.

In some embodiments, the first set of power processing sub-circuits 70021 further includes two second differential signal ports 70211 and 70212, and a power processing unit 70310 arranged between the first differential signal port 7021 and the two second differential signal ports 70211 and 70212.

In some embodiments, the second differential signal port 70211 includes a positive port 70211a and a negative port 70211b, as shown in FIG. 9. The second differential signal port 70212 includes a positive port 70212a and a negative port 70212b.

In some embodiments, as shown in FIG. 9, the power processing unit 70310 includes two pairs of differential coupling lines 70311 and 70312. The first pair of differential coupling lines 70311 includes a positive coupling line 70311a and a negative coupling line 70311b, and the second pair of differential coupling lines 70312 includes a positive coupling line 70312a and a negative coupling line 70312b.

In some embodiments, as shown in FIG. 9, the positive port 7021a of the first differential signal port 7021 is connected to the positive coupling line 70311a of the first pair of differential coupling lines 70311 of the power processing unit 70310. The negative port 7021b of the first differential signal port 7021 is connected to the negative coupling line 70312b of the second pair of differential coupling lines 70312 of the power processing unit 70310. The negative coupling line 70311b of the first pair of differential coupling lines 70311 is connected, e.g., in series, to the positive coupling line 70312a of the second pair of differential coupling lines 70312.

In some embodiments, N corresponding to the second set of power processing sub-circuits 70022 is selected to be 2, as shown in FIG. 9. The second set of power processing sub-circuits 70022 includes one first differential signal port. The first differential signal port is the same port or connected to the second differential signal port 7022 in the first stage of power processing circuits 7001. Merely by way of example, a positive port and a negative port of the first differential signal port of the second set of power processing sub-circuits 70022 are connected to the positive port 7022a and the negative port 7022b of the second differential signal port 7022 in the first stage of power processing circuits 7001. As shown in FIG. 9, the first differential signal port of the second power processing sub-circuit 70022 is marked with same reference numerals 7022a and 7022b as the positive port and the negative port of the second differential signal port 7021 in the second stage of power processing circuits 7001.

In some embodiments, the second set of power processing sub-circuits 70022 further includes two second differential signal ports 70221 and 70222, and a power processing unit 70320 arranged between the first differential signal port 7022 and the two second differential signal ports 70221 and 70222.

In some embodiments, the second differential signal port 70221 includes a positive port 70221a and a negative port 70221b, as shown in FIG. 9. The second differential signal port 70222 includes a positive port 70222a and a negative port 70222b.

In some embodiments, as shown in FIG. 9, the power processing unit 70320 includes two pairs of differential coupling lines 70321 and 70322. The first pair of differential coupling lines 70321 includes a positive coupling line 70321a and a negative coupling line 70321b, and the second pair of differential coupling lines 70322 includes a positive coupling line 70322a and a negative coupling line 70322ib b.

In some embodiments, as shown in FIG. 9, the positive port 7022a of the first differential signal port 7022 is connected to the positive coupling line 70321a of the first pair of differential coupling lines 70321 of the power processing unit 70320. The negative port 7022b of the first differential signal port 7022 is connected to the negative coupling line 70322b of the second pair of differential coupling lines 70322 of the power processing unit 70320. The negative coupling line 70321b of the first pair of differential coupling lines 70321 is connected, e.g., in series, to the positive coupling line 70322a of the second pair of differential coupling lines 70322.

In some embodiments, as shown in FIG. 9, the second differential signal ports 70211, 70212, 70221, and 70222 in the first stage of power processing sub-circuits 70021 and the second stage of power processing sub-circuits 70022 are connected to the power processing unit 70310 and the power processing unit 70320 in a variety of ways.

In some embodiments, as shown in FIG. 9, a positive port and a negative port of each of the second differential signal ports 70211, 70212, 70221, and 70222 are connected to a positive coupling line and a negative coupling line, respectively, of different pairs of differential coupling lines. A positive port and a negative port of a second differential signal port located in a set of power processing sub-circuits may be connected to a differential coupling line of the same set of power processing sub-circuits and a differential coupling line of another set of power processing sub-circuits, respectively. Therefore, in realizing that the second differential signal port can be connected to a positive coupling line and a negative coupling line, respectively, of different pairs of differential coupling lines, it can be spanned across different sets of power processing sub-circuits.

In some embodiments, as shown in FIG. 9, the positive port 70211a of the second differential signal port 70211 of the first set of power processing sub-circuits 70021 is connected to the positive coupling line 70311a of the first pair of differential coupling lines 70311 of the first set of power processing sub-circuits 70021. The negative port 70211b of the second differential signal port 70211 of the first set of power processing sub-circuits 70021 is connected to the negative coupling line 70322b of the second pair of differential coupling lines 70322 of the second set of power processing sub-circuits 70022.

In some embodiments, as shown in FIG. 9, the positive port 70212a of the second differential signal port 70212 of the first set of power processing sub-circuits 70021 is connected to the positive coupling line 70312a of the second pair of differential coupling lines 70312 of the first set of power processing sub-circuits 70021. The negative port 70212b of the second differential signal port 70212 of the first set of power processing sub-circuits 70021 is connected to the negative coupling line 70311b of the first pair of differential coupling lines 70311 of the first set of power processing sub-circuits 70021.

In some embodiments, as shown in FIG. 9, the positive port 70221a of the second differential signal port 70221 of the second set of power processing sub-circuits 70022 is connected to the positive coupling line 70321a of the first pair of positive coupling lines 70321 of the second set of power processing sub-circuits 70022. The negative port 70221b of the second differential signal port 70221 of the second set of power processing sub-circuits 70022 is connected to the negative coupling line 70312b of the second pair of differential coupling lines 70312 of the first set of power processing sub-circuits 70021.

In some embodiments, as shown in FIG. 9, the positive port 70222a of the second differential signal port 70222 of the second set of power processing sub-circuits 70022 is connected to the positive coupling line 70322a of the second pair of differential coupling lines 70322 of the second set of power processing sub-circuits 70022. The negative port 70222b of the second differential signal port 70222 of the second set of power processing sub-circuits 70022 is connected to the negative coupling line 70321b of the first pair of differential coupling lines 70321 of the second set of power processing sub-circuits 70022.

In some embodiments, the power processing circuit further includes an isolation circuit. The isolation circuit is arranged between ports with same polarity of different second differential signal ports in different sets of power processing sub-circuits.

In some embodiments, the isolation circuit in Embodiment 7 is arranged not only between ports with same polarity of different second differential signal ports in a same set of power processing sub-circuits, but may also be arranged between port with same polarity of second differential signal ports in different sets of power processing sub-circuits. The isolation circuit in Embodiment 7 may also span different sets of power processing sub-circuits.

In some embodiments, the isolation circuit includes an isolation resistor, or an isolation resistor and a capacitor that are connected in parallel.

For example, an isolation resistor R7112a is arranged between the positive port 70211a of the second differential signal port 70211 and the positive port 70212a of the second differential signal port 70212. The isolation resistor R7112b is arranged between the negative port 70212b of the second differential signal port 70212 and the negative port 70221b of the second differential signal port 70221.

In some embodiments of the present disclosure, the isolation circuit includes an isolation resistor, or an isolation resistor and a capacitor that are connected in parallel, which helps to slow down a discharge rate of the capacitor's voltage, reduce the impact of short circuits on the circuit, and thereby protect the power processing circuit.

In some embodiments of the present disclosure, the isolation circuit is arranged between ports with same polarity of different second differential signal ports of different sets of power processing sub-circuits, which reduces mutual interference between different sub-circuits, enhances the anti-interference capability, and improves the quality of signal transmission.

In some embodiments of the present disclosure, the isolation circuit is arranged between ports with same polarity of different second differential signals in each stage of power processing circuits, which is conducive to improving the isolation effect and ensuring the accuracy of signal transmission.

In some embodiments, Embodiment 7 is similar to Embodiment 1 in that the isolation can be enhanced by, for example, varying an electrical length of a differential coupling line. There is no need to use a quarter-wavelength coupling line, which reduces the overall size of the circuit, increases integration, and improves insertion loss performance. More content can be found in Embodiment 1 and the related descriptions thereof.

### Embodiment 8

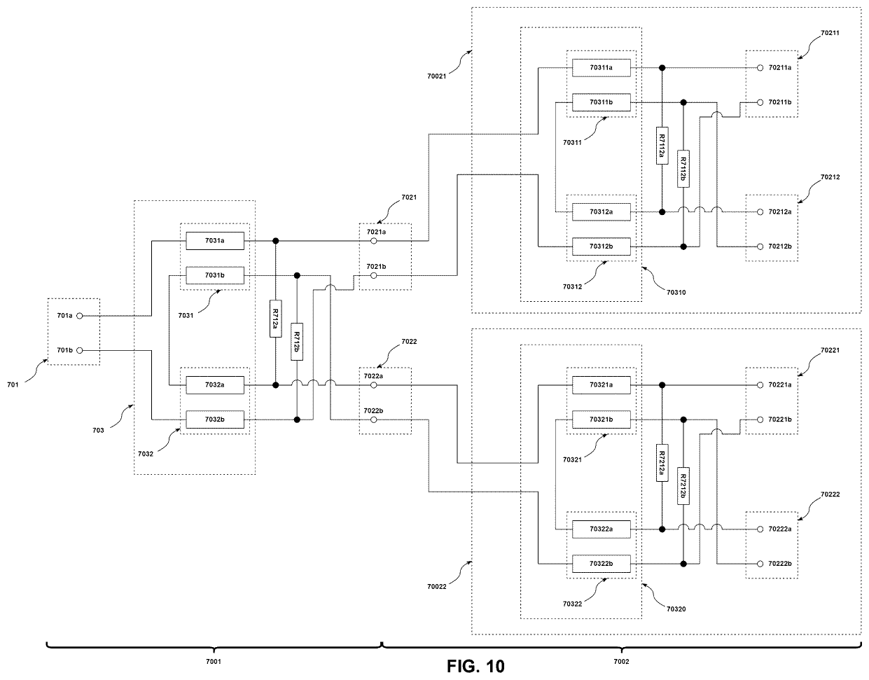

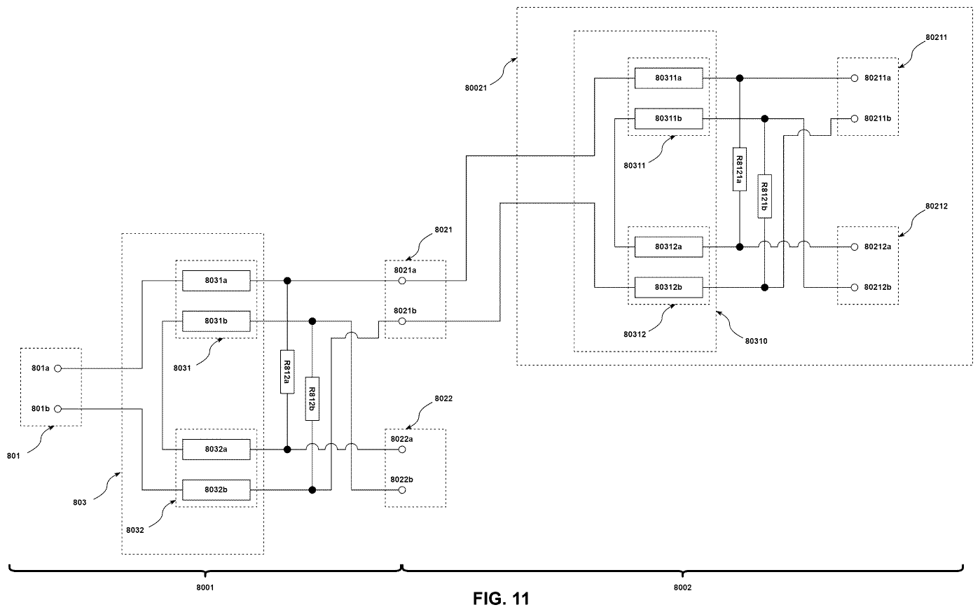

FIG. 10 is a schematic diagram illustrating an exemplary structure of a multi-stage power processing circuit in Embodiment 8 according to the present disclosure.

A difference from an embodiment illustrated in FIG. 9 is that, as illustrated in FIG. 10, in the present embodiment, when a positive port and a negative port of a second differential signal port are connected to a positive coupling line and a negative coupling line, respectively, of different pairs of differential coupling lines, the positive port and the negative port of the second differential signal port is only connected to a positive coupling line and a negative coupling line, respectively, of different pairs of differential coupling lines of a set of power processing sub-circuits in which the second differential signal port is located, i.e., the positive port and the negative port may not be connected to a pair of differential coupling lines of another set of power processing sub-circuits.

For this reason, in this embodiment, only a connection relationship between the second differential signal ports 70211, 70212, 70221, and 70222 in the two sets of power processing sub-circuits 70021 and 70022 and the power processing unit 70310 and the power processing unit 70320 is specifically illustrated.

In some embodiments, as shown in FIG. 10, the positive port 70211a of the second differential signal port 70211 of the first set of power processing sub-circuits 70021 is connected to the positive coupling line 70311a of the first pair of positive coupling lines 70311 of the first set of power processing sub-circuits 70021. The negative port 70211b of the second differential signal port 70211 of the first set of power processing sub-circuits 70021 is connected to the negative coupling line 70312b of the second pair of differential coupling lines 70312 of the first set of power processing sub-circuits 70021.

In some embodiments, as shown in FIG. 10, the positive port 70212a of the second differential signal port 70212 of the first set of power processing sub-circuits 70021 is connected to the positive coupling line 70312a of the second pair of differential coupling lines 70312 of the first set of power processing sub-circuits 70021. The negative port 70212b of the second differential signal port 70212 of the first set of power processing sub-circuits 70021 is connected to the negative coupling line 70311b of the first pair of differential coupling lines 70311 of the first set of power processing sub-circuits 70021.

In some embodiments, as shown in FIG. 10, the positive port 70221a of the second differential signal port 70221 of the second set of power processing sub-circuits 70022 is connected to the positive coupling line 70321a of the first pair of differential coupling lines 70321 of the second set of power processing sub-circuits 70022. The negative port 70221b of the second differential signal port 70221 of the second set of power processing sub-circuits 70022 is connected to the negative coupling line 70322b of the second pair of differential coupling lines 70322 of the second set of power processing sub-circuits 70022.

In some embodiments, as shown in FIG. 10, the positive port 70222a of the second differential signal port 70222 of the second set of power processing sub-circuits 70022 is connected to the positive coupling line 70322a of the second pair of differential coupling lines 70322 of the second set of power processing sub-circuits 70022. The negative port 70222b of the second differential signal port 70222 of the second set of power processing sub-circuits 70022 is connected to the negative coupling line 70321b of the second pair of differential coupling lines 70321 of the second set of power processing sub-circuits 70022.

It will be appreciated that structures of the two sets of power processing sub-circuits have a certain symmetry. For example, the two sets of power processing sub-circuits include a same count of pairs of differential coupling lines, as well as a same count of second differential signal ports.

In some embodiments, it is also possible to design the two sets of power processing sub-circuits to include a different count of pairs of differential coupling lines. For example, a second set of power processing sub-circuits is designed to include three pairs of differential coupling lines. Accordingly, the second set of power processing sub-circuits is provided with three second differential signal ports correspondingly. That is, when a plurality of sets of power processing sub-circuits are included in a same stage of power processing circuits, at least two sets of power processing sub-circuits may be set to have different values of N (i.e., a count of second differential signal ports, and a count of pairs of differential coupling lines).

### Embodiment 9

FIG. 11 is a schematic diagram illustrating an exemplary structure of a multi-stage power processing circuit in Embodiment 9 according to the present disclosure.

A difference from an embodiment illustrated in FIG. 10 is that, in FIG. 11, only one of second differential signal ports in a first stage of power processing circuits 8001 continues to be connected to a second stage of power processing circuits 8002.

In some embodiments, the multi-stage power processing circuit includes two stages of power processing circuit including the first stage of power processing circuits 8001 and the second stage of power processing circuits 8002, as shown in FIG. 11.

In some embodiments, a structure in the first stage of power processing circuits 8001 in FIG. 11 is similar to that of a first stage of power processing circuits shown in FIG. 10, and N in the first stage of power processing circuits 8001 is selected as 2.

In some embodiments, as shown in FIG. 11, the first stage of power processing circuits 8001 includes one first differential signal port 801 and two second differential signal ports 8021 and 8022, and a power processing unit 803 connected between the first differential signal port 801 and the two second differential signal ports 8021 and 8022.

In some embodiments, as shown in FIG. 11, the first differential signal port 801 includes a positive port 801a and a negative port 801b. The second differential signal port 8021 includes a positive port 8021a and a negative port 8021b, and the second differential signal port 8022 includes a positive port 8022a and a negative port 8022b.

In some embodiments, as shown in FIG. 11, the power processing unit 803 includes two pairs of differential coupling lines 8031 and 8032. The first pair of differential coupling lines 8031 includes a positive coupling line 8031a and a negative coupling line 8031b. The second pair of differential coupling lines 8032 includes a positive coupling line 8032a and a negative coupling line 8032b.

In some embodiments, the positive port 801a of the first differential signal port 801 is connected to the positive coupling line 8031a of the first pair of differential coupling lines 8031 of the power processing unit 803, as shown in FIG. 11. The negative port 801b of the first differential signal port 801 is connected to the negative coupling line 8032b of the second pair of differential coupling lines 8032 of the power processing unit 803. The negative coupling line 8031b of the first pair of differential coupling lines 8031 is connected, e.g., in series, to the positive coupling line 8032a of the second pair of differential coupling lines 8032.

In some embodiments, the positive port 8021a of the second differential signal port 8021 is connected to the positive coupling line 8031a of the first pair of differential coupling lines 8031, as shown in FIG. 11. The negative port 8021b of the second differential signal port 8021 is connected to the negative coupling line 8032b of the second pair of differential coupling lines 8032.

In some embodiments, the positive port 8022a of the second differential signal port 8022 is connected to the positive coupling line 8032a of the second pair of differential coupling lines 8032, as shown in FIG. 11. The negative port 8022b of the second differential signal port 8022 is connected to the negative coupling line 8031b of the first pair of differential coupling lines 8031.

In some embodiments, in the first stage of power processing circuits, the positive port 8021a and the negative port 8021b of the second differential signal port 8021 are connected to a positive coupling line and a negative coupling line, respectively, of different pairs of differential coupling lines. The positive port 8022a and the negative port 8022b of the second differential signal port 8022 are also connected to a positive coupling line and a negative coupling line, respectively, of different pairs of differential coupling lines.

In some embodiments, the first stage of power processing circuits further includes an isolation circuit, as shown in FIG. 11. The isolation circuit is arranged between ports with same polarity of different second differential signal ports.

For example, in a circuit illustrated in FIG. 11, isolation resistors serving as the isolation circuit are arranged between ports with same polarity of different second differential signal ports.

In some embodiments, as shown in FIG. 11, two isolation resistors R812a and R812b are set in the first stage of power processing circuits 8001 in FIG. 11. The isolation resistor R812a is arranged between the positive port 8021a of the second differential signal port 8021 and the positive port 8022a of the second differential signal port 8022. The isolation resistor R812b is arranged between the negative port 8021b of the second differential signal port 8021 and the negative port 8022b of the second differential signal port 8022.

In some embodiments of the present disclosure, an isolation between ports in the first stage of power processing circuits 8001 is further improved by a design illustrated in Embodiment 9.

In some embodiments, the power processing circuit 8002 includes only one set of power processing sub-circuits 80021.

In some embodiments, N corresponding to the power processing sub-circuit 80021 is selected to be 2, as shown in FIG. 11.

In some embodiments, the power processing sub-circuit 80021 includes one first differential signal port, as shown in FIG. 11. The first differential signal port is a same port or connected to the second differential signal port 8021 in the first stage of power processing circuits 8001. Merely by way of example, a positive port and a negative port of a first differential signal port of the power processing sub-circuit 80021 are same ports or connected to the positive port 8021a and the negative port 8021b of the second differential signal port 8021 in the first stage of power processing circuits 8001. As shown in FIG. 11, a positive port and a negative port of the first differential signal port of the power processing sub-circuit 80021 are no longer separately provided with accompanying markings, instead, they are represented by the positive port 8021a and the negative port 8021b of the second differential signal port 8021 of the power processing circuit 8001.

In some embodiments, as shown in FIG. 11, the power processing sub-circuit 80021 further includes two second differential signal ports 80211 and 80212, and a power processing unit 80310 arranged between the first differential signal port 8021 and the two second differential signal ports 80211 and 80212.

In some embodiments, the second differential signal port 80211 includes a positive port 80211a and a negative port 80211b, as shown in FIG. 11. The second differential signal port 80212 includes a positive port 80212a and a negative port 80212b.

In some embodiments, as shown in FIG. 11, the power processing unit 80310 includes two pairs of differential coupling lines 80311 and 80312. The first pair of differential coupling lines 80311 includes a positive coupling line 80311a and a negative coupling line 80311b. The second pair of differential coupling lines 80312 includes a positive coupling line 80312a and a negative coupling line 80312b.

In some embodiments, as shown in FIG. 11, the positive port 8021a of the first differential signal port 8021 is connected to the positive coupling line 80311a of the first pair of differential coupling lines 80311 of the power processing unit 80310, and the negative port 8021b of the first differential signal port 8021 is connected to the negative coupling line 80312b of the second pair of differential coupling lines 80312 of the power processing unit 80310. The negative coupling line 80311b of the first pair of differential coupling lines 80311 is connected, e.g., in series, to the positive coupling line 80312a of the second pair of differential coupling lines 80312.

The following describes a connection relationship between the second differential signal ports 80211 and 80212 of the power processing sub-circuit 80021 and the power processing unit 80310.

In some embodiments, as shown in FIG. 11, the positive port 80211a of the second differential signal port 80211 of the power processing sub-circuit 80021 is connected to the positive coupling line 80311a of the first pair of differential coupling lines 80311 of the power processing sub-circuit 80021. The negative port 80211b of the second differential signal port 80211 of the power processing sub-circuit 80021 is connected to the negative coupling line 80312b of the second pair of differential coupling lines 80312 of the power processing sub-circuit 80021.

In some embodiments, as shown in FIG. 11, the positive port 80212a of the second differential signal port 80212 of the power processing sub-circuit 80021 is connected to the positive coupling line 80312a of the second pair of differential coupling lines 80312 of the power processing sub-circuit 80021. The negative port 80212b of the second differential signal port 80212 of the power processing sub-circuit 80021 is connected to the negative coupling line 80312a of the first pair of differential coupling lines 80311 of the power processing sub-circuit 80021.

In some embodiments, the second stage of power processing circuits 8002 further includes an isolation circuit. The isolation circuit is arranged between ports with same polarity of different second differential signal ports in the second stage of power processing circuits 8002. In some embodiments, the isolation circuit is realized using an isolation resistor. Merely by way of example, in FIG. 11, the isolation resistor R8121a is arranged between the positive port 80211a of the second differential signal port 80211 and the positive port 80212a of the second differential signal port 80212. The isolation resistor R8121b is arranged between the negative port 80211b of the second differential signal port 80211 and the negative port 80212b of the second differential signal port 80212.

In some embodiments, based on the actual needs of an interface, at least the first differential signal port is connected to a balun circuit for conversion between single-ended and differential signals. Or, at least the second differential signal port is connected to the balun circuit to enable conversion between single-ended and differential signals.

### Embodiment 10

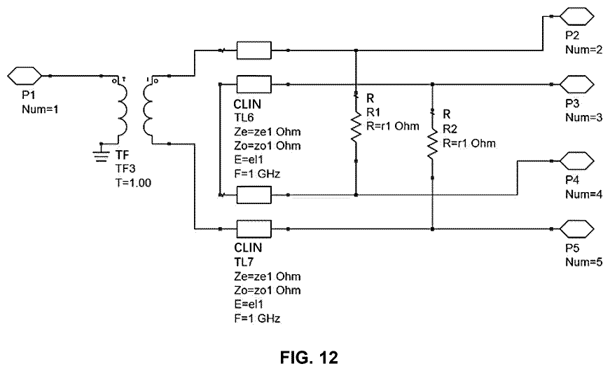

FIG. 12 is a schematic diagram illustrating a principle of a circuit in the prior art according to the present disclosure.

As shown in FIG. 12, a positive coupling line and a negative coupling line of a first pair of differential coupling lines TL6 in the prior art are directly connected to a positive port P2 and a negative port P3 of a same second differential signal port. A positive coupling line and a negative coupling line of a second pair of differential coupling lines TL7 are directly connected to a positive port P4 and a negative port P5 of a same second differential signal port.

In some embodiments, the first pair of differential coupling lines TL6 in FIG. 12 has an even mode impedance Ze of 500 ohm, an odd mode impedance Zo of 12 ohm, and an electrical length E of 25 deg (with respect to an electromagnetic wave of 1 GHz). Isolation resistors R1 and R2 both have a resistance value of 25 ohm. An operating frequency F is 1 GHz. Num denotes a labeling number of a port, and Num=1 denotes a port 1.

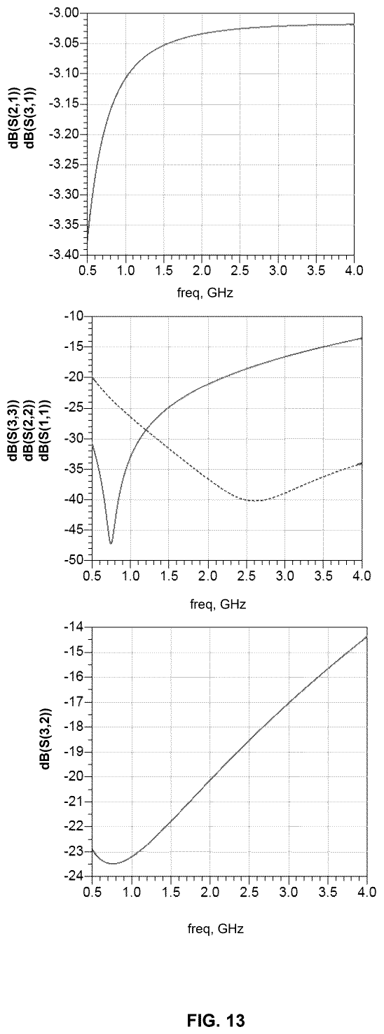

FIG. 13 is a diagram illustrating isolation test results between ports of the circuit in FIG. 12 in the prior art according to some embodiments of the present disclosure.

In some embodiments, results in FIG. 13 are scattering coefficient curves between the ports of the circuit in FIG. 12, measured in practice, which reflects isolation between a positive port and a negative port of a same second differential port in FIG. 12. A horizontal coordinate freg denotes a frequency in GHz and a vertical coordinate denotes isolation in dB.

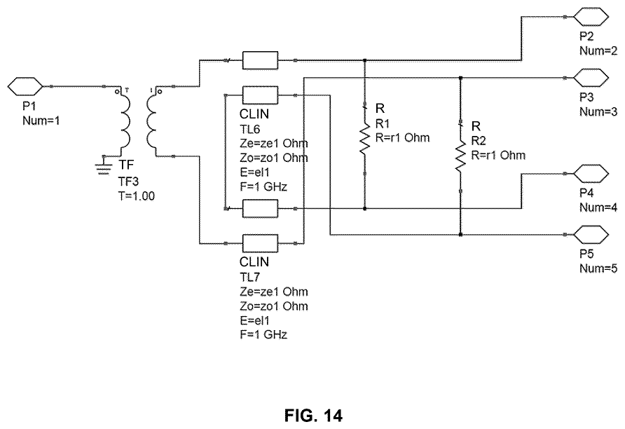

FIG. 14 is a schematic diagram illustrating a principle of the power processing circuit in Embodiment 1 according to the present disclosure.

Device parameter selection results are included in FIG. 14. As shown in FIG. 14, a positive port P2 and a negative port P3 correspond to the positive port 1021a and the negative port 1021b of the second differential signal port 1021 in Embodiment 1 according to the present disclosure. A positive port P4 and a negative port P5 correspond to the positive port 1022a and the negative port 1022b of the second differential signal port 1022 in Embodiment 1 according to the present disclosure. A positive port P1 corresponds to the first differential signal port 101a in Embodiment 1 according to the present disclosure.

In some embodiments, as shown in FIG. 14, a positive coupling line and a negative coupling line of a differential coupling line TL6 correspond to the positive coupling line 1031a and the negative coupling line 1031b, respectively, of the first pair of differential coupling lines 1031 in FIG. 1. A positive coupling line and a negative coupling line of a differential coupling line TL7 correspond to the positive coupling line 1032a and the negative coupling line 1032b, respectively, of the second pair of differential coupling lines 1032 in FIG. 1.

In some embodiments, an isolation resistor R1 corresponds to the isolation resistor R112a in FIG. 1, and an isolation resistor R2 corresponds to the isolation resistor R112b in FIG. 1, as shown in FIG. 14.

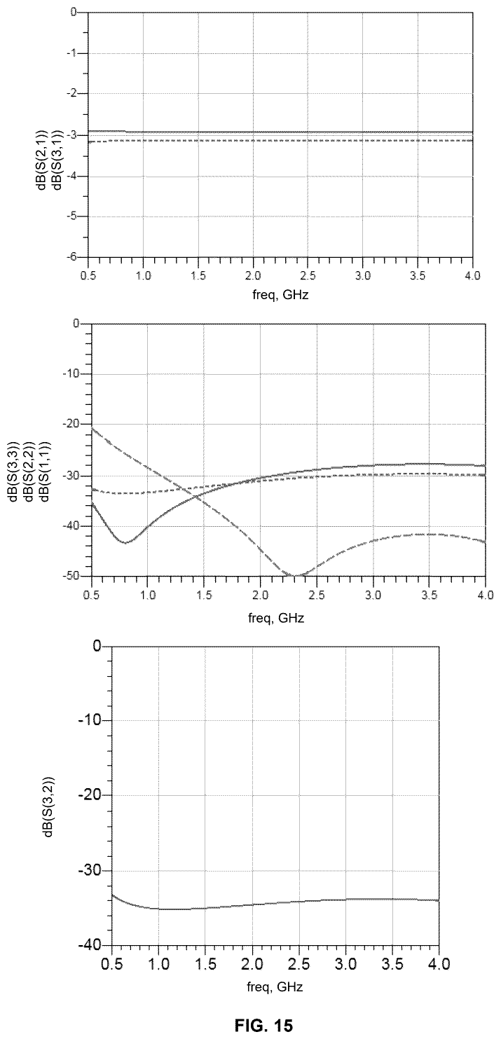

FIG. 15 is a diagram illustrating isolation test results between ports of the power processing circuit in Embodiment 1 according to the present disclosure.

In some embodiments, results in FIG. 15 are scattering coefficient curves between ports of the power processing circuit in FIG. 14, measured in practice, which reflects isolation between a positive port and a negative port of a same second differential port.

In some embodiments, a comparison of actual measurement results in FIG. 13 and FIG. 15 shows that the isolation of a power processing circuit can be further improved by adopting a scheme provided by embodiments of the present disclosure.

It should be noted that the power processing circuit may also be referred to as a power processing sub-circuit module. The isolation circuit may also be referred to as an isolation module. The balun circuit may also be referred to as balun. Each stage of power processing circuits in at least one stage of power processing circuits may also be referred to as a same-stage power processing circuit.

Each embodiment in the present disclosure is described in a recursive manner, and it is sufficient to refer to each other for identical and similar portions of each embodiment, with each embodiment focusing on differences from the other embodiments. In particular, for the system or system embodiments, the descriptions are simpler due to the fact that they are substantially similar to the method embodiments, and it is sufficient to refer to portions of the method embodiments for a description of the relevant aspects. The system and system embodiments described above are merely illustrative. The units described as separate components may or may not be physically distinct. Components displayed as units may or may not be physical units, meaning they can be located in one place or distributed across multiple network units. Some or all of these modules can be selected to fulfill the purpose of the embodiment scheme according to actual needs. One of ordinary skill in the art can understand and implement without creative labor.

The above technical solutions provided in the present disclosure are described in detail, and specific examples are applied herein to illustrate the principles and implementations of the present disclosure, and the above illustrations are only used to assist in the understanding of the method and the core of the present disclosure. At the same time, for those skilled in the art, modifications may be made in the specific embodiments and application scope based on the concepts of the present disclosure. In summary, the contents of the present disclosure should not be construed as a limitation of the present disclosure.

What is claimed is:

1. A power processing circuit, comprising at least one stage of power processing circuits, wherein each stage of the at least one stage of power processing circuits includes at least one set of power processing sub-circuits;
each set of the at least one set of power processing sub-circuits includes a first differential signal port, N second differential signal ports, and a power processing unit connected between the first differential signal port and the N second differential signal ports, the power processing unit includes N pairs of differential coupling lines, where N≥2; and
in each stage of power processing circuits, a positive port and a negative port of at least one second differential signal port are connected to a positive coupling line and a negative coupling line, respectively, of different pairs of differential coupling lines.

2. The power processing circuit of claim 1, wherein in each stage of power processing circuits, a positive port and a negative port of at least one second differential signal port being connected to a positive coupling line and a negative coupling line, respectively, of different pairs of differential coupling lines includes: a positive port and a negative port of each of the at least one second differential signal port is connected to the positive coupling line and the negative coupling line, respectively, of the different pairs of differential coupling lines.

3. The power processing circuit of claim 1, wherein in each stage of power processing circuits, a positive port and a negative port of at least one second differential signal port being connected to a positive coupling line and a negative coupling line, respectively, of different pairs of differential coupling lines includes:
the positive port and the negative port of the at least one second differential signal port are connected to a positive coupling line and a negative coupling line, respectively, of different pairs of differential coupling lines in different sets of power processing sub-circuits in the at least one set of power processing sub-circuits.

4. The power processing circuit of claim 1, wherein each stage of power processing circuits includes an isolation circuit, the isolation circuit is arranged between ports with same polarity of different second differential signal ports in each stage of power processing circuits.

5. The power processing circuit of claim 4, wherein the isolation circuit is arranged between ports with same polarity of different second differential signal ports of a same set of power processing sub-circuits.

6. The power processing circuit of claim 5, wherein the isolation circuit is further arranged between ports with same polarity of different second differential signal ports in different sets of power processing sub-circuits.

7. The power processing circuit of claim 4, wherein the isolation circuit includes an isolation resistor, or an isolation resistor and a capacitor that are connected in parallel.

8. The power processing circuit of claim 1, wherein in each set of power processing sub-circuits, a positive port of the first differential signal port is connected to a positive coupling line of a first pair of differential coupling lines, a negative port of the first differential signal port is connected to a negative coupling line of an N-th pair of differential coupling lines, and a negative coupling line of an i-th pair of differential coupling lines is connected to a positive coupling line of an (i+1)-th pair of differential coupling lines, where 1≤i<N.

9. The power processing circuit of claim 8, wherein a negative coupling line of an i-th pair of differential coupling lines being connected to a positive coupling line of an (i+1)-th pair of differential coupling lines includes:
the negative coupling line of the i-th pair of differential coupling lines is connected to the positive coupling line of the (i+1)-th pair of differential coupling lines in series.

10. The power processing circuit of claim 1, wherein the power processing circuit is a power divider.

11. The power processing circuit of claim 10, wherein in each set of power processing sub-circuits, the first differential signal port serves as a differential signal input end, and the second differential signal ports serve as differential signal output ends.

12. The power processing circuit of claim 1, wherein the power processing circuit is a combiner.

13. The power processing circuit of claim 12, wherein in each set of power processing sub-circuits, the first differential signal port serves as a differential signal output end, and the second differential signal ports serve as differential signal input ends.

14. The power processing circuit of claim 1, wherein at least one first differential signal port is connected to a balun circuit.

15. The power processing circuit of claim 1, wherein the at least one second differential signal port is connected to a balun circuit.

16. The power processing circuit of claim 1, wherein a length of each of the differential coupling lines is less than one-quarter of a wavelength of an electromagnetic wave at an operating center frequency.

17. The power processing circuit of claim 1, wherein in a case where an upper stage of power processing circuits is connected to a lower stage of power processing circuits, at least one second differential signal port in the upper stage of power processing circuits is connected to at least one first differential signal port in the lower stage of power processing circuits.
